(19) United States
(12) Patent Application Publication
(10) Pub. No.: US 2025/0118524 A1
(43) Pub. Date: Apr. 10, 2025

(54) ACTIVELY HEATED TARGET TO GENERATE AN ION BEAM

(71) Applicant: Axcelis Technologies, Inc., Beverly, MA (US)

(72) Inventors: Neil K. Colvin, Merrimack, NH (US); Neil J. Bassom, Hamilton, MA (US); Joshua Abeshaus, Haverhill, MA (US)

(21) Appl. No.: 18/905,177

(22) Filed: Oct. 3, 2024

Related U.S. Application Data
(60) Provisional application No. 63/588,110, filed on Oct. 5, 2023.

(51) Int. Cl. H01J 37/08; H01J 37/317

(52) U.S. Cl. CPC H01J 37/08; H01J 37/3171

(57) ABSTRACT

An arc chamber for an ion source defines a chamber volume, and a target material is disposed within the chamber volume. The target material comprises a dopant species and can be contained in a target member. An indirectly heated cathode is positioned within the chamber volume and ionizes a source gas within the chamber volume, defining a plasma having a plasma thermal emission. A target heater selectively heats the target material independently from the plasma thermal emission associated with the plasma. The target heater can be a resistive heating element, inductive heating element, halogen heating element, or a laser configured to selectively heat at least a portion of the target member. The target member can consist of a solid dopant material or can contain a liquid dopant material.

### REFERENCE TO RELATED APPLICATIONS

This application claims the benefit of U.S. Provisional Application Ser. No. 63/588,110 filed Oct. 5, 2023, entitled, “ACTIVELY HEATED TARGET TO GENERATE AN ION BEAM”, the contents of all of which are herein incorporated by reference in their entirety.

### TECHNICAL FIELD

The present invention relates generally to ion implantation systems, and more specifically to actively heating a target for an ion source, and to enhance etching and sputtering of a target material and provide improved productivity of the ion source.

### BACKGROUND

In the manufacture of semiconductor devices, ion implantation is used to dope semiconductors with impurities. Ion implantation systems are often utilized to dope a workpiece, such as a semiconductor wafer, with ions from an ion beam, in order to either produce n- or p-type material doping, or to form passivation layers during fabrication of an integrated circuit. Such beam treatment is often used to selectively implant the wafers with impurities of a specified dopant material, at a predetermined energy level, and in controlled concentration, to produce a semiconductor material during fabrication of an integrated circuit. When used for doping semiconductor wafers, the ion implantation system injects a selected ion species into the workpiece to produce the desired extrinsic material. Implanting ions generated from source materials such as antimony, arsenic, or phosphorus, for example, results in an “n-type” extrinsic material wafer, whereas a “p-type” extrinsic material wafer often results from ions generated with source materials such as boron, gallium, or indium.

A typical ion implanter includes an ion source, an ion extraction device, a mass analysis device, a beam transport device and a wafer processing device. The ion source generates ions of desired atomic or molecular dopant species. These ions are extracted from the source by an extraction system, typically a set of electrodes, which energize and direct the flow of ions from the source, forming an ion beam. Desired ions are separated from the ion beam in a mass analysis device, typically a magnetic dipole performing mass dispersion or separation of the extracted ion beam. The beam transport device, typically a vacuum system containing a series of focusing devices, transports the ion beam to the wafer processing device while maintaining desired properties of the ion beam. Finally, semiconductor wafers are transferred in to and out of the wafer processing device via a wafer handling system, which may include one or more robotic arms, for placing a wafer to be treated in front of the ion beam and removing treated wafers from the ion implanter.

### SUMMARY

The present disclosure thus provides a system and apparatus for increasing the productivity of an ion source in an ion implantation system. Accordingly, the following presents a simplified summary of the disclosure in order to provide a basic understanding of some aspects of the invention. This summary is not an extensive overview of the invention. It is intended to neither identify key or critical elements of the invention nor delineate the scope of the invention. Its purpose is to present some concepts of the invention in a simplified form as a prelude to the more detailed description that is presented later.

In accordance with one example aspect of the disclosure, an arc chamber for an ion source is provided, wherein the arc chamber defines a chamber volume. A target material, for example, is disposed within the chamber volume, wherein the target material comprises a dopant species. In one example, an indirectly heated cathode is positioned within the chamber volume, wherein the indirectly heated cathode is configured to ionize a source gas within the chamber volume, thereby defining a plasma having a plasma thermal emission associated therewith. Further, a target heater is provided and configured to selectively heat the target material within the chamber volume independently from the plasma thermal emission associated with the plasma. The target heater, for example, can comprise one or more of a resistive heating element, an inductive heating element, a radiative heating element such as a quartz halogen heating element, or a laser.

In one example, a repeller is positioned within the chamber volume, wherein the repeller comprises a repeller shaft and a target member. The target member, for example, contains the target material, and the target heater is configured to selectively heat at least a portion of the repeller shaft, thereby selectively heating the target member. For example, the repeller shaft can comprise a hollow portion and a solid portion, wherein the hollow portion defines a cavity within the repeller shaft. The target heater, for example, can be thus configured to selectively heat the solid portion by a transmission of thermal energy through the cavity.

The target heater, for example, can be positioned within the cavity and comprise one of a resistive heating element or an inductive heating element. The target heater can alternatively comprise one of a quartz halogen heating element or a laser, for example, wherein the target heater is directed toward the solid portion through the cavity. The target heater, for example, may be positioned external to the arc chamber.

The target member, for example, can comprise a hollow cylinder generally encircling the at least a portion of the repeller shaft. The target member, for example, can be separated from the repeller shaft by a gap, or the target member can be in thermally conductive communication with the at least a portion of the repeller shaft.

In another example, the target member comprises a reservoir operably coupled to the repeller shaft, wherein the reservoir is configured to contain the target material in a liquid state therein.

In yet another example, a power source is provided and configured to electrically bias, electrically float, or electrically ground one or more of the target member or the repeller with respect to one or more of the arc chamber, the indirectly heated cathode, or the target heater. The target member, in one example, example, is electrically coupled to the power source. In accordance with another example, the target member is operably coupled to the arc chamber.

The target member, for example, can comprise a target cylinder generally encircling the indirectly heated cathode. For example, the target heater can comprise the indirectly heated cathode. The target member in another example can comprise a reservoir positioned within the arc chamber and configured to contain the target material in a liquid state therein. Alternatively, the target member can comprise or contain the target material in a solid state. For example, the arc chamber can comprise one or more chamber walls, and wherein one or more of the target member or the target heater is operably coupled to the one or more chamber walls.

In accordance with another example aspect, an arc chamber for an ion source is provided, wherein a target member is disposed within the arc chamber, and wherein the target member is configured to contain a dopant material. An indirectly heated cathode is positioned within the arc chamber, wherein the indirectly heated cathode is configured to define a plasma within the arc chamber, and wherein the plasma has a plasma thermal emission associated therewith. A target heater, for example, is further configured to selectively heat the target member independently from the plasma thermal emission associated with the plasma. The target heater can comprise one or more of a resistive heating element, an inductive heating element, a quartz halogen heating element, or a laser.

The arc chamber of the present example can comprise a repeller positioned therein, wherein the target member is proximate to the repeller, and wherein the target heater is configured to selectively heat at least a portion of the repeller, thereby selectively heating the target member. The repeller can comprise a repeller shaft having a hollow portion and a solid portion, wherein the hollow portion defines a cavity within the repeller shaft, and wherein the target heater is configured to selectively heat the solid portion by a transmission of thermal energy through the cavity.

The target can be positioned within the cavity and comprise one of a resistive heating element or an inductive heating element. Alternatively, the target heater can comprise one of a quartz halogen heating element or a laser, wherein the target heater is directed toward the solid portion through the cavity. The target member, for example, can comprise a hollow cylinder generally encircling the at least a portion of the repeller. Again, the target member can be separated from the repeller by a gap.

The target member, for example, can comprise a reservoir operably coupled to the repeller or the arc chamber, wherein the reservoir is configured to contain the dopant material in a liquid state therein. The target member can alternatively, or in addition, comprise a target cylinder generally encircling the indirectly heated cathode, whereby the target heater can additionally comprise the indirectly heated cathode. The arc chamber can further comprise one or more walls, wherein one or more of the target member and the target heater is operably coupled to, or associated with, the one or more walls.

According to another example aspect of the disclosure, a method is provided for controlling an ion source. In one example, the method comprises forming a plasma within an arc chamber, thereby defining a plasma thermal emission. Further, a target member containing a dopant material disposed within the arc chamber is selectively heated independent from the plasma thermal emission. By selectively heating the target member independent from the plasma thermal emission, for example, a faster transition between dopant species at differing temperatures can be advantageously achieved. For example, selectively heating the target member can comprise heating the target member to a predetermined operating temperature prior to forming the plasma within the arc chamber. Alternatively, or in addition, selectively heating the target member can comprise heating the target member to the predetermined operating temperature concurrent with forming the plasma within the arc chamber. The predetermined operating temperature, for example, can be greater than a predetermined plasma temperature associated with heating of target member by the plasma thermal emission, alone.

To the accomplishment of the foregoing and related ends, the disclosure comprises the features hereinafter fully described and particularly pointed out in the claims. The following description and the annexed drawings set forth in detail certain illustrative embodiments of the invention. These embodiments are indicative, however, of a few of the various ways in which the principles of the invention may be employed. Other objects, advantages and novel features of the invention will become apparent from the following detailed description of the invention when considered in conjunction with the drawings.

### BRIEF DESCRIPTION OF THE DRAWINGS

FIG. 1 is a block diagram of an exemplary vacuum system utilizing an ion source in accordance with several aspects of the present disclosure.

FIG. 2 illustrates a perspective view of an ion source in accordance with various example aspects of the present disclosure.

FIG. 3 illustrates a partial cross-sectional view of an arc chamber of the ion source of FIG. 2 in accordance with various example aspects of the present disclosure.

FIG. 4 illustrates a partial cross-sectional view of a repeller assembly and target member in accordance with various example aspects of the present disclosure.

FIG. 5 illustrates a partial cross-sectional view of a repeller assembly and target member in accordance with several examples of the present disclosure.

FIG. 6 illustrates a partial cross-sectional view of another repeller assembly having a solid member extending through a chamber wall in accordance with several examples of the present disclosure.

FIG. 7 illustrates a partial cross-sectional view of another repeller assembly having a solid member heated by an induction coil in accordance with several examples of the present disclosure.

FIG. 8 illustrates a partial cross-sectional view of another repeller assembly reservoir in accordance with several examples of the present disclosure.

FIG. 9 illustrates a cross-sectional view of an indirectly heated cathode having target member comprising a cathode shield in accordance with several examples of the present disclosure.

FIG. 10 is flow diagram of a methodology for heating a target material in accordance with several examples of the present disclosure.

### DETAILED DESCRIPTION

The present disclosure is directed generally toward an ion implantation system and an ion source associated therewith. More particularly, the present disclosure is directed toward an improved arc chamber and components associated therewith for said ion source, whereby productivity of the ion source is improved.

Accordingly, the present invention will now be described with reference to the drawings, wherein like reference numerals may be used to refer to like elements throughout. It is to be understood that the description of these aspects are merely illustrative and that they should not be interpreted in a limiting sense. In the following description, for purposes of explanation, numerous specific details are set forth in order to provide a thorough understanding of the present invention. It will be evident to one skilled in the art, however, that the present invention may be practiced without these specific details. Further, the scope of the invention is not intended to be limited by the embodiments or examples described hereinafter with reference to the accompanying drawings, but is intended to be only limited by the appended claims and equivalents thereof.

It is also noted that the drawings are provided to give an illustration of some aspects of embodiments of the present disclosure and therefore are to be regarded as schematic only. In particular, the elements shown in the drawings are not necessarily to scale with each other, and the placement of various elements in the drawings is chosen to provide a clear understanding of the respective embodiment and is not to be construed as necessarily being a representation of the actual relative locations of the various components in implementations according to an embodiment of the invention. Furthermore, the features of the various embodiments and examples described herein may be combined with each other unless specifically noted otherwise.

It is also to be understood that in the following description, any direct connection or coupling between functional blocks, devices, components, elements or other physical or functional units shown in the drawings or described herein could also be implemented by an indirect connection or coupling. Furthermore, it is to be appreciated that functional blocks or units shown in the drawings may be implemented as separate features in one embodiment, and may also or alternatively be fully or partially implemented in a common feature in another embodiment.

Ion sources (commonly referred to as arc ion sources) generate ion beams used in implanters and can include heated filament cathodes for creating ions that are shaped into an appropriate ion beam for wafer treatment. U.S. Pat. No. 5,497,006 to Sferlazzo et al., for example, discloses an ion source having a cathode supported by a base and positioned with respect to a gas confinement chamber for ejecting ionizing electrons into the gas confinement chamber. The cathode of the Sferlazzo et al. is a tubular conductive body having an endcap that partially extends into the gas confinement chamber. A filament is supported within the tubular body and emits electrons that heat the endcap through electron bombardment, thereby thermionically emitting ionizing electrons into the gas confinement chamber to form a plasma.

A repeller is positioned opposite the cathode, where a target source material can be provided near the repeller, wherein ion source gases such as fluorine or other volatile species can enhance chemical etching of the target material based on heat provided solely from the plasma.

Gas feeds are the preferred method of supplying material to an ion source to generate ions for implantation. In some cases, gaseous sources of desired atoms or molecules are not conveniently available, however. In such cases, a solid target containing the target material (e.g., Al₂O₃, AlN, GaN, or GaAs for Al and Ga ions) are provided that are capable of withstanding temperatures within the ion source. Alternatively, a container holding a material that is liquid at high temperatures (e.g., pure Al) may be held or inserted into the arc chamber.

An aggressive chemistry such as the halogens fluorine, chlorine, bromine, or iodine or a halide-based molecule such as Cl₂, CCl₄, BCl₃, Br₂, I₂, HCl, HBr, HI, CHCl₃, CBr₄, CHBr₃, CHₓI_{y}, F₂, BF₃, NF₃, PF₃, XeF₂, or SF₆ are used to enhance the removal of material from the target and transport it into the plasma.

The rates of such chemical etching, however, is highly temperature dependent, whereby it may take wait times up to 30 minutes from a cold-start condition to yield the required beam current for production. A similar condition can also occur when changing from a first dopant species to a second dopant species, in situations where and the power required to generate the acceptable beam current for the first dopant species is significantly lower than the power required to generate acceptable beam current for the second dopant species. Such wait times substantially reduce the productivity of the ion implanter.

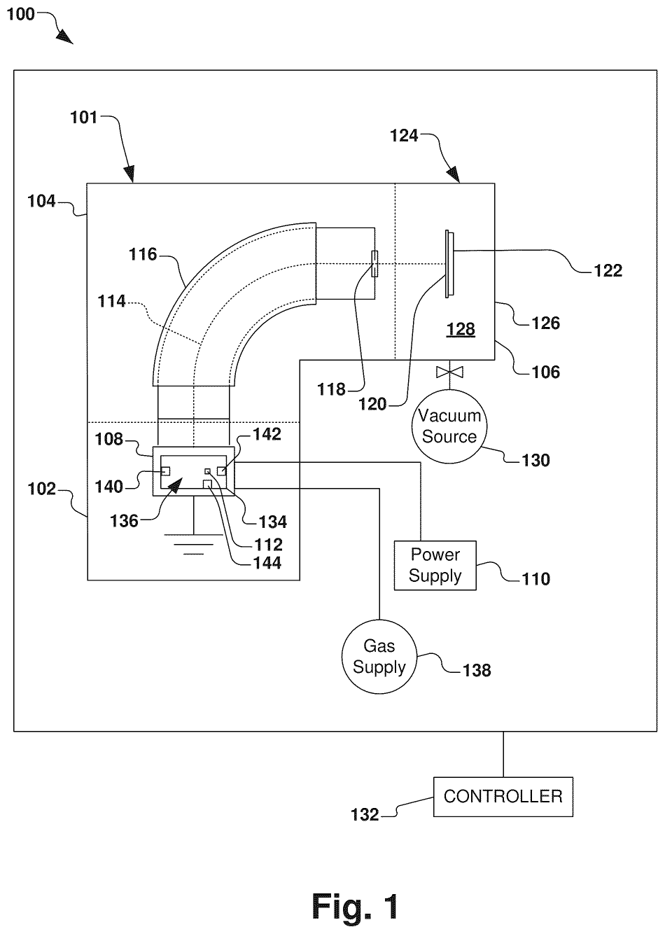

In order to gain an appreciation of the present disclosure, FIG. 1 illustrates an exemplified vacuum system 100 that may implement various apparatus, systems, and methods of the present disclosure. The vacuum system 100 in the present example comprises an ion implantation system 101, however various other types of vacuum systems are also contemplated, such as plasma processing systems, or other semiconductor processing systems. The ion implantation system 101, for example, comprises a terminal 102, a beamline assembly 104, and an end station 106.

Generally speaking, an ion source 108 in the terminal 102 is coupled to a power supply 110, whereby a target material 112 (e.g., a dopant material) is ionized into a plasma to form an ion beam 114. The ion beam 114 in the present example is directed through a beam-steering apparatus 116, and out an aperture 118 towards the end station 106. In the end station 106, the ion beam 114 bombards a workpiece 120 (e.g., a semiconductor such as a silicon wafer, a display panel, etc.), which is selectively clamped or mounted to a chuck 122 (e.g., an electrostatic chuck or ESC). Once embedded into the lattice of the workpiece 120, the implanted ions change the physical and/or chemical properties of the workpiece. Because of this, ion implantation is used in semiconductor device fabrication and in metal finishing, as well as various applications in materials science research.

The ion beam 114 of the present disclosure can take any form, such as a pencil or spot beam, a ribbon beam, a scanned beam, or any other form in which ions are directed toward end station 106, and all such forms are contemplated as falling within the scope of the disclosure.

According to one exemplary aspect, the end station 106 comprises a process chamber 124, such as a vacuum chamber 126, wherein a process environment 128 is associated with the process chamber. The process environment 128 within the process chamber 124, for example, comprises a vacuum produced by a vacuum source 130 (e.g., a vacuum pump) coupled to the process chamber and configured to substantially evacuate the process chamber. Further, a controller 132 is provided for overall control of the vacuum system 100.

The present disclosure provides an apparatus configured to increase productivity of the ion source 108 while decreasing downtime of the ion implantation system 101, such as when changing dopant species, or during start-up operation of the system. It shall be understood that the apparatus of the present disclosure may be implemented in various semiconductor processing equipment such as CVD, PVD, MOCVD, etching equipment, and various other semiconductor processing equipment, and all such implementations are contemplated as falling within the scope of the present disclosure.

In one example, the ion source 108 comprises an arc chamber 134 (also called an ion source chamber) that generally defines a chamber volume 136, whereby the arc chamber can be constructed using refractory metals (W, Mo, Ta, etc.) and graphite in order to provide suitable high temperature performance, whereby such materials are generally accepted by semiconductor chip manufacturers.

In accordance with the present disclosure, the target material 112, for example, is provided in solid or liquid form within the chamber volume 136, wherein the target material comprises a dopant species (e.g., Al, Ga). A gas supply 138, for example, is fluidly coupled to the chamber volume 136, whereby an etchant gas having aggressive chemistry can be used to etch or otherwise enhance a removal of the target material 112 to transport the dopant species into the plasma. Examples of etchant gases from the gas supply 138 can include halogens, such as fluorine, chlorine, bromine, or iodide or a halide-based molecule such as Cl₂, CCl₄, BCl₃, Br₂, I₂, HCl, HBr, HI, CHCl₃, CBr₄, CHBr₃, CHₓI_{y}, F₂, BF₃, NF₃, PF₃, XeF₂ or SF₆.

The present disclosure appreciates that rates of chemical etching, however, is highly temperature dependent. When starting a conventional ion implantation system, for example, large wait times can be required from a so-called cold-start condition in order to yield an acceptable ion beam current for production. Similar wait times can be conventionally seen when changing from a first dopant species to a second dopant species. For example, when a first power required to generate an acceptable beam current for the first dopant species is significantly lower than a second power required to generate acceptable beam current for the second dopant species, conventional wait times associated with increasing the temperature within the ion source by the plasma, alone, can substantially reduce the productivity of the ion implanter.

The present disclosure advantageously reduces an amount of time needed to reach an acceptable temperature within the arc chamber 134, and thus improve operation and productivity of the ion implantation system by independently heating the target material from the heating provided by the plasma. As such, a reduction in the time to reach a desired operating temperature of the ion source 108 is achieved to achieve a desired ion beam current. Further, the present disclosure advantageously provides an ability to heat the target material 112 within the chamber volume 136 to a higher temperature than has been conventionally achieved using the plasma alone, thereby increasing the rates of etching reaction with the target material, as well as providing increased beam currents.

In accordance with one non-limiting example, the ion source 108 can include an indirectly heated cathode 140 that is provided within the chamber volume 136, wherein the indirectly heated cathode is configured to further ionize the target material 112 within the chamber volume 136 via a control of the power supply 110, thus defining the plasma having a plasma thermal emission associated therewith. A repeller 142, for example, may be further provided generally opposite the indirectly heated cathode 140.

In general, in accordance with various examples that will be provided infra, a target heater 144 is further provided and configured to selectively heat the target material 112 independently from the plasma thermal emission associated with the plasma. The target heater 144, for example, can comprise one or more of a resistive heating element, an inductive heating element, a radiative heating element such as a quartz halogen heating element, and a laser.

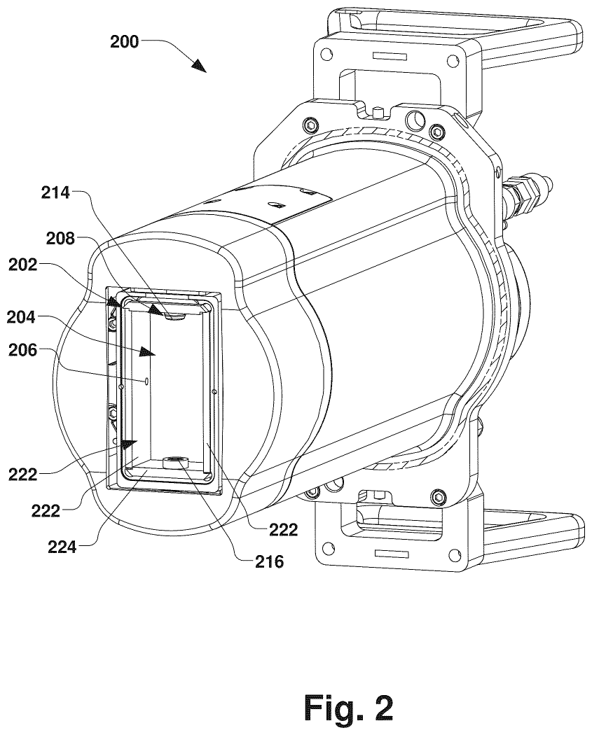

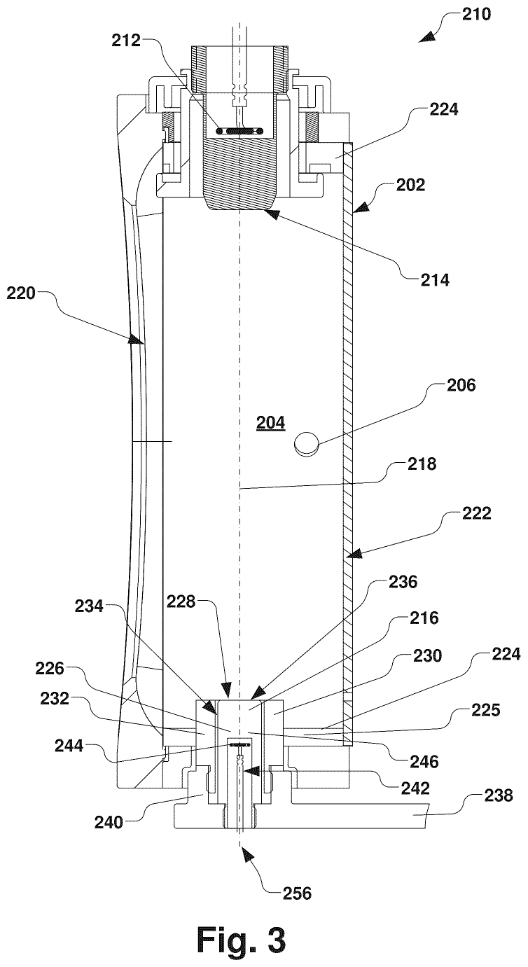

In accordance with various example aspects of the disclosure, an example ion source 200 is illustrated in FIG. 2, wherein various aspects of the disclosure will be discussed in greater detail. The ion source 200 of FIG. 2 comprises an arc chamber 202 configured for forming an ion beam (not shown). The ion source 200, for example, generates the ion beam by ionizing a source gas introduced to a chamber volume 204 of the arc chamber 202 through a source gas inlet 206. The source gas inlet 206, for example can be fluidly coupled to the gas supply 138 of FIG. 1 for introduction of the source gas and/or etchant gas to the chamber volume 204 of the arc chamber 202 of FIG. 2. The ionization process and formation of a plasma (not shown) within the chamber volume 204, for example, is effectuated by an exciter 208, which may take the form of a thermally heated filament, a filament heating a cathode (indirectly heated cathode “IHC”), or a radio frequency (RF) antenna. In accordance with the present disclosure, the arc chamber 202 of the ion source 200 of the present example is associated with an IHC ion source 210, as illustrated in greater detail in FIG. 3.

The IHC ion source 210, for example, comprises a filament 212, an indirectly heated cathode 214 and a repeller 216 (e.g., an anti-cathode). In the present example, the repeller 216 and the indirectly heated cathode 214 are positioned opposite of one another generally along an axis 218 in the arc chamber 202. It shall be noted that while the repeller 216 is illustrated as being opposite the indirectly heated cathode, while not shown, one or more additional repellers may be further provided in various other positions within the arc chamber 202, wherein the one or more additional repellers can have a structure similar to the repeller 216 shown. An aperture 220 is further provided, through which the ion beam 114 of FIG. 1 emerges. In one example, a source magnet (not illustrated) can provide a magnetic field (not shown) generally along the axis 218 of FIG. 3 between the cathode 214 and repeller 216. During operation of an IHC ion source 210, for example, the filament 212 is resistively heated to temperatures high enough to emit electrons, which are in turn accelerated to bombard the indirectly heated cathode 214 that is maintained at a potential that is positive with respect to the filament.

The indirectly heated cathode 214, for example, is heated to temperatures high enough for it to thermally emit electrons into the arc chamber 202, which is held at a potential that is positive with respect to the cathode in order to accelerate the electrons. The magnetic field helps confine the electrons along field lines between the indirectly heated cathode 214 and repeller 216 in order to reduce the loss of electrons to one or more chamber walls 222 of the arc chamber 202. The loss of electrons is further reduced by the repeller 216, which can be held at the potential of the indirectly heated cathode 214 in order to reflect electrons back toward the cathode. The excited electrons ionize the source gas, thus generating a plasma (not shown). Ions are thus extracted through the aperture 220 and electrostatically accelerated to form a high energy ion beam by an electrode positioned outside the arc chamber 202.

In operation, the indirectly heated cathode 214 (e.g., a cathode composed of tungsten or tantalum) is indirectly heated via the filament 212 and is used to start and sustain the ion source plasma (e.g., a thermionic electron emission). The indirectly heated cathode 214 and the repeller 216, for example, are at a negative potential in relation to the one or more chamber walls 222 (e.g., one or more tungsten liners) of the arc chamber 202, and both the cathode and repeller can be sputtered by the ionized gases.

A repeller shaft 226 of the repeller 216, for example, can be constructed from one or more of tungsten, tantalum, molybdenum, or graphite. In the present example, a top repeller portion 228 of the repeller shaft 226 is exposed to the plasma within the internal volume and is coaxially aligned with the indirectly heated cathode 214 along the axis 218.

In accordance with a general aspect of the present disclosure, a target member 230 is provided proximate to the repeller shaft 226, whereby the target member is configured to contain a dopant material in one of a solid or liquid form. As illustrated, the target member 230 is in a solid form and is generally cylindrical, encircling the repeller shaft 226. The target member 230, for example, can be comprised of a target material 232 that is configured to be chemically etched and sputtered by the ion source plasma. In one example, the target material is a ceramic comprising a metal (e.g., aluminum nitride, aluminum oxide, or aluminum carbide). The metal, for example, has a melting temperature of greater than 400 C. It should be noted that while the present example describes the target material 232 in one example as being an aluminum-based ceramic, the present disclosure further contemplates the target material 232 being any high temperature ceramic containing a metal other than aluminum. In yet another example, the target material is comprised of a metal having a melting temperature of greater than 400 C.

In one example, the target member 230 can be operably coupled to the one or more chamber walls 222, such as being mechanically and/or electrically coupled to the one or more chamber walls 222. For example, the target member 230 can be mechanically and/or electrically coupled to one or more liners 224 associated with the one or more chamber walls 222, such as being operably coupled to a bottom liner 225, wherein the bottom liner is at a return or ground potential. The target member 230 in the present example is further configured to provide a gap 234 between the target member 230 and the repeller shaft 226. The gap 234, for example, radially surrounds the repeller shaft 226, and can be approximately 0.25 mm or greater.

The target member 230 and/or the repeller shaft 226, for example, can be electrically grounded or positively biased, negatively biased, or electrically floating with respect to the arc chamber 202. In the present example, the target member 230 and repeller shaft 226 do not physically or electrically contact one another. However, while not shown in FIG. 3, the target member 230 and the repeller shaft 226 may contact one another or otherwise provide thermal and/or electrical conduction therebetween. Further, while not shown, in other examples, the target member 230 may be slightly higher or lower than a top repeller surface 236 of the repeller shaft 226 by a small margin (e.g., approximately 1 mm), which may be associated with the gap 234. The gap 234, in one example, can provide significant gas conductance within the gap to further expose the target member 230 to further enhance the chemical etching and sputtering of the target material 232.

In one example, the target member 230 is comprised of an aluminum-containing ceramic (e.g., AlN and Al₂O₃), whereby an etchant gas (e.g., a halide gas) is injected into the arc chamber 202 via one or more of the source gas inlet 206. The etchant gas, for example, can comprise a chlorinated or fluorinated gas such as Cl₂, Cl₃, BF₃, SiF₄, or PF₃, a bromide gas, an iodide gas, or another halide gas. In an example where the etchant gas comprises a fluorinated gas, the fluorinated gas is cracked in the plasma during operation of the arc chamber 202 to yield fluorine, whereby the fluorine etches the aluminum from target member 230. The fluorinated gas (e.g., a dopant gas or a mixture of an inert gas and fluorine gas) is thus further channeled to the gap 234 between the repeller shaft 226 and the target member 230. The target member 230, for example, can be further coupled to a support member 238, whereby the support member can be at an electrical potential of the indirectly heated cathode 214, electrically biased to the indirectly heated cathode, or can be electrically grounded or insulated from other components.

In accordance with another example aspect, the target member 230 can be operably coupled to a target support 240, wherein the target support is configured to support the target member while providing no direct contact between the target member and the repeller shaft 226. Alternatively, the target member 230 and the repeller shaft 226 can directly contact one another.

In accordance with another aspect, the repeller shaft 226, for example, is comprised of a conductive refractory metal (e.g., tungsten), while the target member 230 is generally non-conductive or insulative (e.g., a ceramic such as AlN) that is electrically biased or floating (e.g., charged to predetermined potential). The repeller shaft 226, being negative biased, generates a negative field, such that a voltage applied to the repeller shaft accelerates positive charged ions in proximity thereto. As such, a voltage drop (called a sheath), accelerates the ions. The greater the bias applied to the repeller shaft 226, the greater the energy in the acceleration that is achieved. Thus, the repeller shaft 226 increases ion generation efficiency.

In accordance with the present disclosure, a target heater 242 is further provided, whereby the target heater is configured to selectively heat the target member 230, and thus, the target material 232, independently from the plasma thermal emission associated with the plasma discussed above. The target heater 242 in the present example comprises a resistive heating element 244 (e.g., a resistive heating filament) that can be electrically coupled to the power supply 110 of FIG. 1 and controlled by the controller 132 for selective activation thereof.

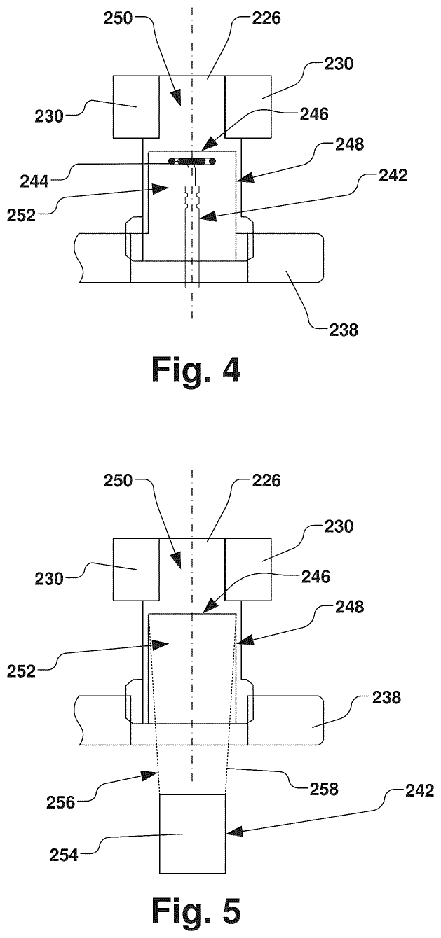

Referring again to FIG. 3, the target heater 242, for example, is configured to selectively heat at least a portion 246 of the repeller shaft 226. Accordingly, the repeller shaft 226 is further configured to selectively heat the target member 230. For example, the repeller shaft 226 can comprise a hollow portion 248 and a solid portion 250, as illustrated in greater detail in another example in FIG. 4, wherein the hollow portion defines a cavity 252 within the repeller shaft 226. The target heater 242, for example, can be thus configured to selectively heat the solid portion 250 by a transmission of thermal energy through the cavity 252. As illustrated in FIG. 4, the repeller shaft 226 and the target member 230 are in direct contact with one another. However, while not shown, it should be noted that the repeller shaft 226 and the target member 230 may be in close proximity to one another in other examples, where no direct contact is made therebetween.

FIG. 5 illustrates an example whereby the target heater 242 comprises an emission source 254, such as a quartz halogen heating element, and a laser. As illustrated, the target heater 242 provides energy 256 (e.g., thermal radiation, laser excitation, etc.) toward the repeller shaft 226 (e.g., into the hollow portion 248), thereby selectively heating the at least a portion 246 (e.g., the solid portion 250) of the repeller shaft. In the case of the emission source 254 being a laser, the energy 256 comprises a laser beam 258.

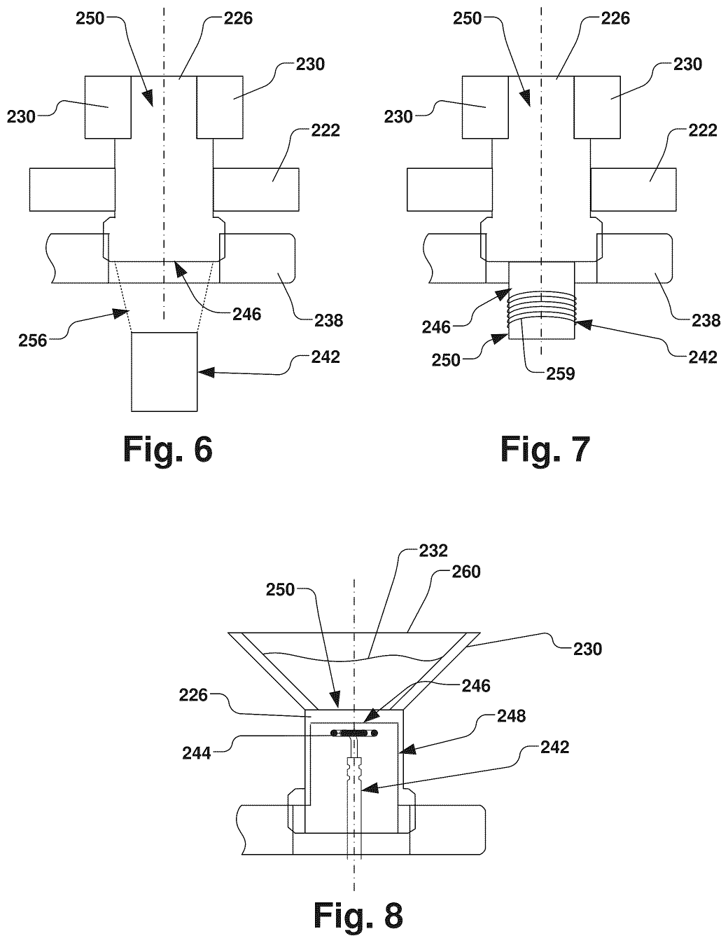

The present disclosure contemplates the target heater 242 heating any portion of the target member 230, thus advantageously increasing an etching of the target member due, at least in part, to the increased temperature of the target member. The repeller shaft 226, for example, can be solid or hollow, and the at least a portion 246 of the repeller shaft can be positioned either internal or external to the arc chamber 202 of FIG. 3. For example, as illustrated in FIG. 6, the repeller shaft 226 is generally solid, whereby the solid portion 250 of the repeller shaft is selectively heated by the target heater 242. The target heater 242, in another example, can comprise an inductive coil 259, such as illustrated in FIG. 7. The inductive coil 259, for example, is configured to inductively heat the solid portion 250, whereby an alternating electromagnetic field induces electric current in the repeller shaft 226, whereby the energy 256 is provided within the repeller shaft, itself.

The at least a portion 246 of the repeller shaft 226 illustrated in FIGS. 6-7, for example, can be positioned external to the one or more chamber walls 222, whereby the target heater 242 selectively heats the repeller shaft and thus the target member 230. It shall be noted that the target heater 242 illustrated in FIG. 6 can comprise the emission source 254 discussed above, or the target heater can alternatively comprise any of a resistive heating element, inductive heating element, quartz halogen heating element, laser, or any heating apparatus configured to selectively heat the target member while remaining generally external to the arc chamber.

In accordance with another example, as illustrated in FIG. 8, the target member 230 comprises a reservoir 260 operably coupled to the repeller shaft 226, wherein the reservoir is configured to contain the target material 232 in a liquid state therein. The target heater 242, for example, is further configured to selectively heat at the least a portion 246 (e.g., the solid portion 250 of the repeller shaft 226), thereby selectively heating the target material 232 residing in the reservoir 260. The reservoir 260, for example, can be further electrically coupled to the power supply 110 of FIG. 1, whereby the reservoir can be electrically biased, floating, or grounded with respect to one or more of the arc chamber 134 and indirectly heated cathode 140. The target heater 242, for example, may be further configured to heat the target material 232 in order to transition the target material from a solid phase to a liquid phase when the target material resides in the reservoir 260.

In another example, the target member is operably coupled to any portion of the arc chamber 134, wherein the target member contains the target material 112. For example, while note shown, one or more of the target member 230 and the target heater 242 are operably coupled to the one or more chamber walls 222 of the arc chamber 202 shown in FIG. 3. For example, the target member 230 can comprise a plate (not shown) that takes the place of at least a portion of one of the one or more chamber walls 222, whereby the target heater 242 is configured to selectively heat the one or more chamber walls.

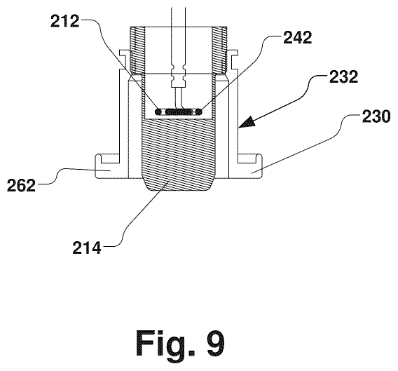

In yet another example, as illustrated in FIG. 9, the target member 230 can comprise a shield 262 associated with the indirectly heated cathode 214. In the present example, the target heater 242 comprises the filament 212, whereby the filament is further configured to heat the shield 262. The shield 262, for example, encircles or otherwise surrounds the indirectly heated cathode 214, and can be the same electrical potential of the indirectly heated cathode, or at ground or return potential. Again, the target member 230 of the present disclosure can be advantageously heated to a high temperature to aid in the etching (e.g., increase the etch rate) of the target material 112 therefrom via the interaction with the etchant gas discussed above, whereby the heating of the target member is independent of heat associated with the plasma formed in the arc chamber. In some examples, the target heater 242 is configured to heat the target member 230 to temperatures greater than those that can be achieved by the plasma, alone. For example, the target heater 242 can be configured to selectively heat the target member 230 to high temperatures reaching approximately 500 C-1000 C. In other examples, the target heater 242 can be configured to selectively heat the target member 230 to high temperatures exceeding 1000 C.

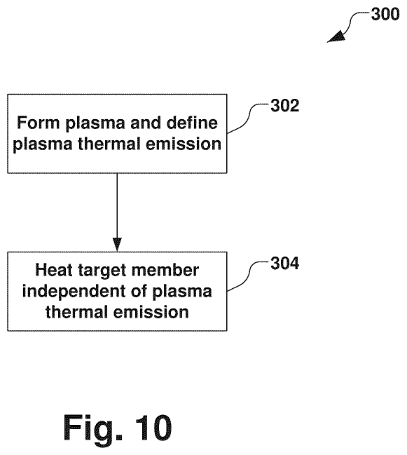

In accordance with yet another example aspect of the present disclosure, a method 300 is provided for controlling an ion source in FIG. 10, whereby various features discussed above may be utilized in practicing the method. It should be noted that while exemplary methods are illustrated and described herein as a series of acts or events, it will be appreciated that the present invention is not limited by the illustrated ordering of such acts or events, as some steps may occur in different orders and/or concurrently with other steps apart from that shown and described herein, in accordance with the invention. In addition, not all illustrated steps may be required to implement a methodology in accordance with the present invention. Moreover, it will be appreciated that the methods may be implemented in association with the systems illustrated and described herein as well as in association with other systems not illustrated.

In accordance with one example, the method 300 comprises forming a plasma within an arc chamber, thereby defining a plasma thermal emission in act 302. In act 304, a target member disposed within the arc chamber is selectively heated. The target member contains a dopant material, as discussed in various examples above. In accordance with the present disclosure, the selective heating of the target member in act 304 is performed independently from forming the plasma in act 302. For example, selectively heating the target member in act 304 comprises heating the target member to a predetermined operating temperature prior to forming the plasma within the arc chamber. In another example, the act of selectively heating the target member in act 304 comprises heating the target member to a predetermined operating temperature concurrent with the act of forming the plasma within the arc chamber in act 302. The predetermined operating temperature, for example, can be greater than a predetermined plasma temperature associated with heating of target member by the plasma thermal emission, alone.

Although the invention has been shown and described with respect to a certain embodiment or embodiments, it should be noted that the above-described embodiments serve only as examples for implementations of some embodiments of the present invention, and the application of the present invention is not restricted to these embodiments. In particular regard to the various functions performed by the above described components (assemblies, devices, circuits, etc.), the terms (including a reference to a “means”) used to describe such components are intended to correspond, unless otherwise indicated, to any component which performs the specified function of the described component (i.e., that is functionally equivalent), even though not structurally equivalent to the disclosed structure which performs the function in the herein illustrated exemplary embodiments of the invention. In addition, while a particular feature of the invention may have been disclosed with respect to only one of several embodiments, such feature may be combined with one or more other features of the other embodiments as may be desired and advantageous for any given or particular application. Accordingly, the present invention is not to be limited to the above-described embodiments, but is intended to be limited only by the appended claims and equivalents thereof.

1. An ion source, comprising:
an arc chamber defining a chamber volume therein;
a target material disposed within the chamber volume, wherein the target material comprises a dopant species;
an indirectly heated cathode positioned within the chamber volume, wherein the indirectly heated cathode is configured to ionize a source gas within the chamber volume, thereby defining a plasma having a plasma thermal emission associated therewith; and
a target heater configured to selectively heat the target material within the chamber volume independently from the plasma thermal emission associated with the plasma.

2. The ion source of claim 1, wherein the target heater comprises one or more of a resistive heating element, an inductive heating element, a quartz halogen heating element, or a laser.

3. The ion source of claim 1, further comprising a repeller positioned within the chamber volume, wherein the repeller comprises a repeller shaft and a target member, wherein the target member contains the target material, and wherein the target heater is configured to selectively heat at least a portion of the repeller shaft, thereby selectively heating the target member.

4. The ion source of claim 3, wherein the repeller shaft comprises a solid portion, wherein the target heater is configured to selectively heat the solid portion by a transmission of thermal energy thereto.

5. The ion source of claim 4, wherein the repeller shaft further comprises a hollow portion, wherein the hollow portion defines a cavity within the repeller shaft, and wherein the target heater is configured to selectively heat the solid portion by a transmission of thermal energy through the cavity.

6. The ion source of claim 5, wherein the target heater is positioned within the cavity and comprises one of a resistive heating element or an inductive heating element.

7. The ion source of claim 5, wherein the target heater comprises one of a quartz halogen heating element and a laser, wherein the target heater is directed toward the solid portion through the cavity.

8. The ion source of claim 3, wherein the target member comprises a hollow cylinder generally encircling the at least a portion of the repeller shaft.

9. The ion source of claim 3, wherein the target member comprises a reservoir operably coupled to the repeller shaft, wherein the reservoir is configured to contain the target material in a liquid state therein.

10. The ion source of claim 3, further comprising a power source configured to electrically bias, electrically float, or electrically ground the repeller with respect to the arc chamber.

11. The ion source of claim 10, wherein the target member is electrically coupled to the power source.

12. The ion source of claim 1, further comprising a target member operably coupled to the arc chamber, wherein the target member contains the target material.

13. The ion source of claim 12, further comprising a power source configured to electrically bias, electrically float, or electrically ground the target member with respect to one or more of the arc chamber, the indirectly heated cathode, or the target heater.

14. The ion source of claim 12, wherein the target member comprises a target cylinder generally encircling the indirectly heated cathode.

15. The ion source of claim 14, wherein the target heater comprises the indirectly heated cathode.

16. The ion source of claim 12, further wherein the target member comprises a reservoir configured to contain the target material in a liquid state therein.

17. The ion source of claim 12, wherein the target member comprises the target material in a solid state.

18. The ion source of claim 12, wherein the arc chamber comprises one or more chamber walls, and wherein one or more of the target member and the target heater is operably coupled to the one or more chamber walls.

19. An ion source, comprising:
an arc chamber defining a chamber volume therein;
an indirectly heated cathode positioned within the chamber volume, wherein the indirectly heated cathode is configured to define a plasma within the chamber volume, and wherein the plasma has a plasma thermal emission associated therewith;
a repeller positioned generally opposite the indirectly heated cathode within the chamber volume, wherein the repeller comprises a repeller shaft and a target member, wherein the target member contains a dopant material; and
a target heater configured to selectively heat at least a portion of the repeller shaft, thereby selectively heating the target member, wherein the target heater is configured to selectively heat the target member independently from the plasma thermal emission associated with the plasma.

20. The ion source of claim 19, wherein the target heater comprises one or more of a resistive heating element, an inductive heating element, a quartz halogen heating element, or a laser.

21. The ion source of claim 20, wherein the repeller shaft comprises a solid portion, wherein the target heater is configured to selectively heat the solid portion by a transmission of thermal energy thereto.

22. The ion source of claim 21, wherein the repeller shaft further comprises a hollow portion, wherein the hollow portion defines a cavity within the repeller shaft, and wherein the target heater is configured to selectively heat the solid portion by a transmission of thermal energy through the cavity.

23. The ion source of claim 21, wherein the target member comprises a hollow cylinder generally encircling the at least a portion of the repeller shaft.

24. The ion source of claim 21, wherein the target member comprises a reservoir operably coupled to the repeller shaft, wherein the reservoir is configured to contain the dopant material in a liquid state therein.

25. The ion source of claim 21, further comprising one or more chamber walls, wherein one or more of the target member or the target heater is operably coupled to the one or more chamber walls.
